(19) United States
(12) Patent Application Publication
(10) Pub. No.: US 2014/0264612 A1
(43) Pub. Date: Sep. 18, 2014

(54) GROWTH OF EPITAXIAL SEMICONDUCTOR REGIONS WITH CURVED TOP SURFACES

(71) Applicant: INTERNATIONAL BUSINESS MACHINES CORPORATION, Armonk, NY (US)

(72) Inventors: KANGGUO CHENG, Schenectady, NY (US); ALI KHAKIFIROOZ, Mountain View, CA (US); ALEXANDER REZNICEK, Troy, NY (US); THOMAS N. ADAM, Slingerlands, NY (US)

(73) Assignee: International Business Machines Corporation, Armonk, NY (US)

(21) Appl. No.: 13/834,514

(22) Filed: Mar. 15, 2013

(51) Int. Cl. H01L 27/088; H01L 29/66; H01L 21/02

(52) U.S. Cl. CPC H01L 27/088; H01L 21/02104; H01L 29/66477
USPC 257/368; 438/478; 438/197

(57) ABSTRACT

Embodiments include epitaxial source/drain regions having curved top surfaces and methods of forming the same. According to an exemplary embodiment, an epitaxial semiconductor region having a curved top surface may be formed by providing a region having a substantially planar bottom made of semiconductor material and sidewalls made of non-semiconductor material substantially perpendicular to the planar bottom, depositing a semiconductor layer having a crystalline portion on the flat bottom and amorphous portions on the sidewalls using a low pressure chemical vapor deposition process with a nitrogen carrier gas, and removing the amorphous portions from the sidewalls. To further increase the thickness of the epitaxial semiconductor region, the method may cycle between depositing a semiconductor layer having a crystalline portion on the flat bottom and amorphous portions on the sidewalls; and removing the amorphous portions on the sidewalls until the combined thickness of all the crystalline portions reaches a desired thickness.

### BACKGROUND

The present invention generally relates to epitaxially growth processes, and more specifically to growing epitaxial source/drain regions with rounded top surfaces for field effect transistors (FETs).

FETs may include a semiconductor substrate containing a source region and a drain region spaced apart by a channel region. A FET with an n-type source region and drain region may be referred to as an nFET. A FET with a p-type source region and drain region may be referred to as a pFET. The channel region may be undoped or have opposite doping than the source region and the drain region. A gate electrode may be formed above the channel region. By applying voltage to the gate electrode, the conductivity of the channel region may increase and allow current to flow from the source region to the drain region. Metal contacts may be formed to the source and drain regions to apply current to the source and drain regions.

To reduce resistance between the metal contacts and the source and drain regions, silicide regions, which may be more conductive than the source and drain regions, may be formed between the source and drain regions and the metal contacts. Typically, the silicide regions are formed by depositing a metal layer on the source and drain regions and then annealing the FET, causing the metal layer to react with the semiconductor material of the source and drain regions.

As FETs continue to become smaller in size, the contact area between the metal contact and the source/drain region, as well as the volume of silicide that may be formed on the source and drain regions, decreases. As a result, the resistance between the metal contact and the source and drain regions may increase. Therefore, a method of increasing the contact area and the volume of silicide between the metal contact and the source and drain regions is desirable in part to decrease resistance.

### BRIEF SUMMARY

The present invention relates epitaxial semiconductor regions having curved top surfaces, and methods of forming the same. According to an exemplary embodiment, an epitaxial semiconductor region having a curved top surface may be formed by first providing a region having a substantially planar bottom made of semiconductor material and sidewalls made of non-semiconductor material substantially perpendicular to the planar bottom. A semiconductor layer may then be deposited in the region using a low pressure chemical vapor deposition process with a nitrogen carrier gas. The semiconductor layer may have a crystalline portion on the flat bottom and amorphous portions on the sidewalls. The amorphous portions may then be removed from the sidewalls, leaving the crystalline portion on the bottom of the region.

According to another exemplary embodiment, a semiconductor device may be formed by first forming a microelectronic device including a first and second gate above a semiconductor substrate separated by a region, a first spacer on a sidewall of the first gate adjacent to the region, and a second spacer on the second gate adjacent to the region. A source/drain region having a curved top surface and a desired height may then be formed in the region by cycling between depositing a semiconductor layer having a crystalline portion on the semiconductor substrate and amorphous portions on the first spacer and the second spacer in the region using a low pressure chemical vapor deposition process with a nitrogen carrier gas, and removing the amorphous portions from the first spacer and the second spacer until the combined height of all the crystalline portions reaches the desired height.

According to another exemplary embodiment, a semiconductor device may include a first and second gate above a semiconductor substrate separated by a region, a first spacer on a sidewall of the first gate adjacent to the region, a second spacer on the second gate adjacent to the region, and a source/drain region adjacent to the semiconductor substrate between the first spacer and the second spacer, wherein the source/drain region has a flat surface abutting the semiconductor substrate and a curved surface opposite the flat surface.

### BRIEF DESCRIPTION OF THE SEVERAL VIEWS OF THE DRAWINGS

The following detailed description, given by way of example and not intend to limit the invention solely thereto, will best be appreciated in conjunction with the accompanying drawings, in which:

FIG. 1 is a cross-sectional front elevational view depicting an extremely-thin semiconductor-on-insulator (ETSOI) substrate, according to an embodiment of the present invention;

FIG. 2 is a cross-sectional front elevational view depicting forming a plurality of gates and a first plurality of spacers above the ETSOI substrate, according to an embodiment of the present invention;

FIG. 3 is a cross-sectional front elevational view depicting growing a first curved epitaxial layer above the ETSOI substrate, according to an embodiment of the present invention;

FIG. 4 is a cross-sectional front elevational view depicting removing amorphous semiconductor material from the plurality of spacers;

FIG. 5 is a cross-sectional front elevational view depicting growing a second curved epitaxial layer above the first curved epitaxial layer, according to an embodiment of the present invention;

FIG. 6 is a cross-sectional front elevational view depicting removing amorphous semiconductor material from the plurality of spacers, according to an embodiment of the present invention;

FIG. 7 is a cross-sectional front elevational view depicting growing a third curved epitaxial layer above the second curved epitaxial layer, according to an embodiment of the present invention, according to an embodiment of the present invention;

FIG. 8 is a cross-sectional front elevational view depicting removing amorphous semiconductor material from the plurality of spacers, according to an embodiment of the present invention;

FIG. 9 is a cross-sectional front elevational view depicting a plurality of source/drain regions having curved top surfaces adjacent to the plurality of spacers, according to an embodiment of the present invention;

FIG. 10 is a cross-sectional front elevational view depicting forming a second plurality of spacers above the plurality of source/drain regions adjacent to the first plurality of spacers, according to an embodiment of the present invention;

FIG. 11 is a cross-sectional front elevational view depicting depositing a metal layer above the plurality of source/drain regions, according to an embodiment of the present invention; and

FIG. 12 is a cross-sectional front elevational view depicting depositing a plurality of silicide layers above the plurality of source/drain regions, according to an embodiment of the present invention.

Elements of the figures are not necessarily to scale and are not intended to portray specific parameters of the invention. For clarity and ease of illustration, dimensions of elements may be exaggerated. The detailed description should be consulted for accurate dimensions. The drawings are intended to depict only typical embodiments of the invention, and therefore should not be considered as limiting the scope of the invention. In the drawings, like numbering represents like elements.

### DETAILED DESCRIPTION

Exemplary embodiments now will be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

Referring to FIG. 1, an extremely-thin semiconductor-on-insulator (ETSOI) substrate 100 may be provided. While an ETSOI substrate is specifically disclosed, it should be noted that the processes described below in FIGS. 2-12 may be performed on a variety of substrates, including, for example, both typical SOI substrates having thicker SOI layers and bulk semiconductor substrates. The substrate 100 may include a base substrate 115, a buried insulator (BOX) layer 125, and a semiconductor-on-insulator (SOI) layer 135. The base substrate 115 may be made from any of several known semiconductor materials including, for example, silicon, germanium, silicon-germanium alloy, carbon-doped silicon, carbon-doped silicon-germanium alloy, and compound (e.g. III-V and II-VI) semiconductor materials. Non-limiting examples of compound semiconductor materials include gallium arsenide, indium arsenide, and indium phosphide, or combinations thereof. Typically the base substrate 115 may be approximately, but is not limited to, several hundred microns thick. For example, the base substrate 115 may include a thickness ranging from approximately 0.5 mm to approximately 1.5 mm.

The BOX layer 125 may be formed from any of several known insulator materials. Non-limiting examples include, for example, oxides, nitrides and oxynitrides of silicon. Oxides, nitrides and oxynitrides of other elements are also envisioned. In addition, the BOX layer 125 may include crystalline or non-crystalline insulator material. Moreover, the BOX layer 125 may be formed using any of several known methods. Non-limiting examples include ion implantation methods, thermal or plasma oxidation or nitridation methods, chemical vapor deposition methods and physical vapor deposition methods. The BOX layer 125 may include a thickness ranging from approximately 10 nm to approximately 80 nm. In one embodiment, the BOX layer 125 may be approximately 20 nm thick.

The SOI layer 135 may include any of the several semiconductor materials included in the base substrate 115. In general, the base substrate 115 and the SOI layer 135 may include either identical or different semiconducting materials with respect to chemical composition, dopant concentration and crystallographic orientation. The SOI layer 135 includes a thickness ranging from approximately 3 nm to approximately 20 nm. While an ETSOI substrate is depicted, embodiments of the present invention may also include typical SOI substrates, where SOI layer 135 may have a thickness of up to approximately 100 nm. Methods for forming the SOI layer 135 are well known in the art. Non-limiting examples include SIMOX (Separation by Implantation of Oxygen), wafer bonding, and ELTRAN® (Epitaxial Layer TRANsfer).

Referring to FIG. 2, a microelectronic device 200 may be formed from the SOI layer 135 by forming a plurality of gates 205 above the SOI layer 135 and forming a first plurality of spacers 215 adjacent to the sidewalls of the plurality of gates 205. The plurality of gates 205 may be formed by any known gate fabrication process, including both gate-first and gate-last processes. In an exemplary gate-first process, each of the plurality of gates 205 may include a gate dielectric layer, a gate electrode, and a hard cap (not shown), and may be formed by any method known in the art, including depositing a stack of layers on the SOI layer 135, masking the stack of layers using photolithography, and etching to remove unwanted material from the stack of layers (not shown). In embodiments where a gate-last process is used, plurality of gates 205 may include a sacrificial polysilicon layer that will later be removed and replaced with, for example, a replacement metal gate structure.

The first plurality of spacers 215 may be formed on the sidewalls of the plurality of gates 205. The first plurality of spacers 215 may be made of, for example, silicon nitride, silicon oxide, silicon oxynitrides, or a combination thereof, and may be formed by any method known in the art, including depositing a conformal silicon nitride layer over the plurality of gates 205 and removing unwanted material from the conformal silicon nitride layer using a anisotropic etching process such as, for example, reactive ion etching (RIE) or plasma etching (not shown). The first plurality of spacers 215 may have a thickness of approximately 2 nm to approximately 100 nm, preferably approximately 2 nm to approximately 50 nm. Methods of forming spacers are well-known in the art and other methods are explicitly contemplated. Further, in various embodiments, the first plurality of spacers 215 may include one or more layers.

Referring to FIGS. 3-9, a two-step epitaxial growth process may be used to form a plurality of source/drain regions 915 (FIG. 9) above the SOI layer 135 adjacent to the first plurality of spacers 215. It should be noted that while the embodiments depicted in FIGS. 3-9 include forming epitaxial source/drain regions on a semiconductor SOI layer substrate between two non-semiconductor spacers, embodiments further include forming any epitaxial region having a substantially planar bottom surface and curved top surface on any semiconductor substrate between any two non-semiconductor regions, where the non-semiconductor regions form sidewalls substantially perpendicular to the semiconductor substrate.

The two-step epitaxial growth process includes a deposition step where epitaxial material is deposited on the SOI layer 135 and an etch step where epitaxial material that may have formed during the deposition step is removed. The two-step process may be repeated a number of times to build up a layer of epitaxial material until a desired thickness is reached. In FIGS. 3-4, a first epitaxial layer is formed on the SOI layer 135, with the deposition step being described below in relation to FIG. 3 and the etch step being described in relation to FIG. 4. In FIGS. 5-6, a second epitaxial layer is formed on the first epitaxial layer. In FIGS. 7-8, a third epitaxial layer is formed on the second epitaxial layer. In FIG. 9, a plurality of source/drain regions 915 are depicted after having been formed by repeating the two-step epitaxial growth process many times.

Referring to FIG. 3, a layer of epitaxial semiconductor material may be deposited above the microelectronic device 200. As a result of the process conditions described below, the layer of semiconductor material will have first crystalline portions 315 grown on semiconductor material such as the SOI layer 135, and first amorphous portions 325 grown on non-semiconductor regions, such as the plurality of gates 205 and the first plurality of spacers 215. Due to the growth of the amorphous portions 325, the crystalline portions cannot grow uniformly parallel to the SOI layer 135. Instead, the crystalline portions will grow thicker at their center and thinner at the intersection with the amorphous portions 325, resulting in the crystalline portions 315 having a convex curved top surface.

The semiconductor layer may be formed using a low pressure chemical vapor deposition (CVD) process utilizing known semiconductor precursors and a nitrogen carrier gas. The CVD process may occur at temperatures below 600° C. and pressures of approximately 2 torr to approximately 20 torr, preferably approximately 5 torr to approximately 10 torr, with a nitrogen carrier gas flow rate of approximately 5 standard liters per minute (slm) to approximately 15 slm, preferably approximately 10 slm to 12 slm. In an exemplary embodiment, the CVD process may occur at a pressure of less than 10 torr with a nitrogen carrier gas flow rate of 11 slm. In an exemplary embodiment, the semiconductor precursors may be silane, monomethylsilane, disilane, and phosphine to form a phosphorus-doped carbon-silicon layer. However, other known precursors may be used to form other semiconductor layers, including, for example, doped and undoped silicon, doped and undoped silicon-germanium, and doped and undoped silicon-germanium-carbon.

Referring to FIG. 4, the amorphous portions 325 may be removed by using an etching process capable of selectively removing amorphous semiconductor material without removing crystalline semiconductor material. An exemplary selective process may include gas-phase etching of the amorphous portions 325 using chlorine or hydrogen chloride gas. The gas-phase etch may occur at approximately 200 torr to approximately 760 torr, preferably approximately 250 torr to approximately 350 torr with an etchant flow rate of approximately 1 slm to approximately 20 slm, preferably approximately 10 slm to approximately 12 slm. The gas-phase etch may occur at approximately 500° C. or above where chlorine gas is used, or 600° C. or above where hydrochloric acid gas is used. In a preferred embodiment, the etching step occurs at a higher temperature than the deposition step.

Referring to FIGS. 5-6, the two-step epitaxial growth process may be repeated to first form a second semiconductor layer consisting of second crystalline portions 515 above the first crystalline portions 315, and second amorphous portions 525 on the first plurality of spacers 215, and then remove the second amorphous portions 525 from the microelectronic device 200 (FIG. 6). In an embodiment, the deposition step depicted in FIG. 5 and the etching step depicted in FIG. 6 may be performed using the same processes as the deposition described above in conjunction with FIG. 3 and the etching step described above in conjunction with FIG. 4, respectively. In an alternate embodiment, the conditions of the second deposition step and the second etching step may be tuned so that the second crystalline portions 515 have different characteristics than the first crystalline portions 315, such as thickness, dopant concentration, etc.

Referring to FIGS. 7-8, the two-step epitaxial growth process may be repeated again to first form a third semiconductor layer consisting of third crystalline portions 715 above first crystalline portions 315 and second crystalline portions 515, and third amorphous portions 725 on the first plurality of spacers 215, and then remove the third amorphous portions 725 from the microelectronic device 200 (FIG. 6). In an embodiment, the deposition step depicted in FIG. 5 and the etching step depicted in FIG. 6 may be performed using the same processes as the deposition described above in conjunction with FIG. 3 and the etching step described above in conjunction with FIG. 4, respectively. In an alternate embodiment, the conditions of the second deposition step and the second etching step may be tuned so that the third crystalline portions 715 has different characteristics than the first crystalline portions 315 and/or the second crystalline portions 515, such as thickness, dopant concentration, etc.

Referring to FIG. 9, a plurality of source/drain regions 915 may be formed by repeating the two-step epitaxial growth process described above in conjunction with FIGS. 3-4, until the source/drain regions 915 reach a desired height. For example, the two-step epitaxial growth process may be repeated 15 to 30 times. It should be noted that the semiconductor layers formed in FIGS. 3-8 are for illustrative purposes only and that the layers formed by the process described by the two-step epitaxial growth process may be much thinner than depicted. In an exemplary embodiment, each cycle of the two-step epitaxial growth process may produce a layer having an average thickness of approximately 0.8 nm to approximately 1.7 nm. In some embodiments, the thickness of each layer may grow with each subsequent deposition. Each of the plurality of source/drain regions 915 may have a height, or radius, of x, measured from the base of the plurality of source/drain regions 915 to the apex of each of the plurality of source/drain regions 915, where x is approximately 10 nm to approximately 100 nm. Each of the plurality of source/drain regions 915 may have a curvature, measured as the inverse of the radius, of approximately 0.01 nm⁻¹ to approximately 0.1 nm⁻¹.

Referring to FIG. 10, a second plurality of spacers 1015 may optionally be formed on the sidewalls of the plurality of first spacers 215 to in part to prevent the silicide layers subsequently formed from potentially expanding into the SOI layer 135. The second plurality of spacers 1015 may be made of, for example, silicon nitride, silicon oxide, silicon oxynitrides, or a combination thereof, and may be formed by any method known in the art, including depositing a conformal silicon nitride layer over the microelectronic device 200 and removing unwanted material from the conformal silicon nitride layer using a anisotropic etching process such as, for example, reactive ion etching (RIE) or plasma etching (not shown). The second plurality of spacers 1015 may have a thickness of approximately 2 nm to approximately 100 nm, preferably approximately 2 nm to approximately 50 nm. Methods of forming spacers are well-known in the art and other methods are explicitly contemplated. Further, in various embodiments, the second plurality of spacers 1015 may include one or more layers.

Referring to FIGS. 11-12, silicide layers 1215 (FIG. 12) may be formed on the exposed portions of the plurality of source/drain regions 915. The silicide layer 1215 may be formed by depositing a metal layer 1115 (FIG. 11) on the source/drain regions 915, and then annealing the metal layer 1115 to react the metal layer 1115 with the plurality of source/drain regions 915. The metal layer 1115 may be made of any suitable metal capable of forming a silicide layer, including for example nickel, platinum, titanium, cobalt or some combination thereof. The annealing process may be performed, for example, by a rapid thermal annealing (RTA) process at peak temperatures ranging from approximately 300 to approximately 900 degrees Celsius, depending on the material composition of metal layer 1115. Due to the curved top surface of the plurality of source/drain regions 915, the silicide layers 1215 may have a greater thickness toward the apex of the plurality of source/drain regions 915 relative to the sides of the plurality of source/drain regions 915. The process of forming silicide layers is well known in the art and it will be understood that other suitable methods may be used to form the silicide layers 1215, including, for example, a trench silicide process.

Because of the curved top surface of the plurality of source/drain regions 915, of source/drain regions 915 have a greater surface area compared to having a flat top surface. The greater surface area may result, among other benefits, in a greater volume of silicide formation and increased contact area with a subsequently formed metal contact. This in turn may result in reduced resistance at the junction between the metal contact and the source/drain region, improving device performance.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein. It is therefore intended that the present invention not be limited to the exact forms and details described and illustrated but fall within the scope of the appended claims.

What is claimed is:

1. A method of forming an epitaxial semiconductor region having a curved top surface, the method comprising:
providing a region having a substantially planar bottom made of semiconductor material and sidewalls made of non-semiconductor material substantially perpendicular to the planar bottom;
depositing a semiconductor layer using a low pressure chemical vapor deposition process with a nitrogen carrier gas, wherein the semiconductor layer has a crystalline portion on the flat bottom and amorphous portions on the sidewalls; and
removing the amorphous portions from the sidewalls.

2. The method of claim 1, wherein the low pressure chemical vapor deposition process occurs at pressures ranging from approximately 2 torr to approximately 20 torr.

3. The method of claim 1, wherein the low pressure chemical vapor deposition process has a nitrogen carrier gas flow rate of approximately 5 standard liters per minute (slm) to approximately 15 slm.

4. The method of claim 1, wherein the crystalline portion of the semiconductor layer has an average thickness of approximately 0.8 nm to approximately 1.7 nm.

5. The method of claim 1, further comprising cycling between:
depositing a semiconductor layer having a crystalline portion on the flat bottom and amorphous portions on the sidewalls; and
removing the amorphous portions on the sidewalls until the combined thickness of all the crystalline portions reaches a desired thickness.

6. The method of claim 5, wherein the desired thickness of all the crystalline portions ranges from approximately 10 nm to approximately 100 nm.

7. The method of claim 5, wherein the top surface of all the crystalline portions has a curvature ranging from approximately 0.01 nm⁻¹ to approximately 0.1 nm⁻¹.

8. A method of forming a semiconductor device, the method comprising:
forming a microelectronic device including a first and second gate above a semiconductor substrate separated by a region, a first spacer on a sidewall of the first gate adjacent to the region, and a second spacer on the second gate adjacent to the region; and
forming a source/drain region, having a curved top surface and a desired height, in the region by cycling between:
depositing a semiconductor layer in the region using a low pressure chemical vapor deposition process with a nitrogen carrier gas, wherein the semiconductor layer has a crystalline portion on the semiconductor substrate and amorphous portions on the first spacer and the second spacer, and
removing the amorphous portions from the first spacer and the second spacer
until the combined height of all the crystalline portions reaches the desired height.

9. The method of claim 8, wherein the low pressure chemical vapor deposition process occurs at pressures ranging from approximately 2 torr to approximately 20 torr.

10. The method of claim 8, wherein the low pressure chemical vapor deposition process has a nitrogen carrier gas flow rate of approximately 5 standard liters per minute (slm) to approximately 15 slm.

11. The method of claim 8, wherein each of the crystalline portions of the semiconductor layer has an average thickness ranging from approximately 0.8 nm to approximately 1.7 nm.

12. The method of claim 8, wherein the desired height of the source/drain region ranges from approximately 10 nm to approximately 100 nm.

13. The method of claim 8, wherein the curved top surface of the source/drain region has a curvature ranging from approximately 0.01 nm⁻¹ to approximately 0.1 nm⁻¹.

14. The method of claim 8, further comprising:
forming a third spacer adjacent to the first spacer;
forming a fourth spacer adjacent to the second; and
forming a silicide layer above the source/drain region by depositing a metal layer above the source/drain region and annealing the semiconductor device.

15. The method of claim 14, wherein the silicide layer has a greater thickness at the apex of the curved top surface of the source/drain region and a lesser thickness adjacent to the third spacer and the fourth spacer.

16. A semiconductor device comprising:
a first and second gate above a semiconductor substrate separated by a region;
a first spacer on a sidewall of the first gate adjacent to the region;
a second spacer on the second gate adjacent to the region; and
a source/drain region adjacent to the semiconductor substrate between the first spacer and the second spacer, wherein the source/drain region has a flat surface abutting the semiconductor substrate and a curved surface opposite the flat surface.

17. The semiconductor device of claim 16, wherein the source/drain region has a height, measured from the flat surface of the source/drain region to the apex of the curved surface of the source/drain region, of approximately 10 nm to approximately 100 nm.

18. The semiconductor device of claim 16, wherein the curved top surface of the source/drain region has a curvature of the top surface ranging from approximately 0.01 nm⁻¹ to approximately 0.1 nm⁻¹.

19. The semiconductor device of claim 16, further comprising:
a third spacer adjacent to the first spacer;
a fourth spacer adjacent to the second spacer; and
a silicide layer above the source/drain region between the third spacer and the fourth spacer.

20. The semiconductor device of claim 19, wherein the silicide layer has a greater thickness at the apex of the curved top surface of the source/drain region and a lesser thickness adjacent to the third spacer and the fourth spacer.
